(19) United States
(12) Patent Application Publication
(10) Pub. No.: US 2025/0140562 A1
(43) Pub. Date: May 1, 2025

(54) LOW RESISTIVITY METAL STACKS AND METHODS OF DEPOSITING THE SAME

(71) Applicant: Applied Materials, Inc., Santa Clara, CA (US)

(72) Inventors: Zhaoxuan Wang, Mountain View, CA (US); Wenting Hou, San Jose, CA (US); Jianxin Lei, Saratoga, CA (US); Qixin Shen, Sunnyvale, CA (US); Hang Yu, San Jose, CA (US)

(73) Assignee: Applied Materials, Inc., Santa Clara, CA (US)

(21) Appl. No.: 18/922,669

(22) Filed: Oct. 22, 2024

Related U.S. Application Data
(60) Provisional application No. 63/546,319, filed on Oct. 30, 2023.

(51) Int. Cl. H01L 21/285; H01L 21/02

(52) U.S. Cl. CPC H01L 21/28506; H01L 21/0217

(57) ABSTRACT

Metal stacks and methods of depositing a metal stack on a semiconductor substrate are disclosed. The metal stack is formed by depositing a tungsten (W) layer on the semiconductor substrate and depositing a molybdenum (Mo) layer on the tungsten (W) layer. In one method, a tungsten (W) capping layer is deposited on the molybdenum (Mo) layer, followed by formation of a nitride capping layer on the tungsten (W) capping layer). In a second method, a nitride capping layer is formed on the molybdenum (Mo) layer using an ammonia free process. Both processes result in the formation of a metal stack having low resistivity.

### CROSS REFERENCE TO RELATED APPLICATIONS

This application claims priority to U.S. Provisional Application Ser. No. 63/546,319, filed Oct. 30, 2023, the entire disclosure of which is hereby incorporated by reference herein.

### TECHNICAL FIELD

Embodiments of the disclosure relate to metal stacks. More particularly, embodiments of the disclosure are directed to low resistivity metal stacks and methods of depositing the same.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such a device is a complementary metal-oxide-semiconductor (CMOS) field effect transistor (FET) or MOSFET, including both planar and three-dimensional structures. An example of a three-dimensional structure is a FinFET device.

An exemplary FinFET or MOSFET includes a gate electrode on a gate dielectric layer on a surface of a semiconductor substrate. Source/drain regions are provided along opposite sides of the gate electrode. The source and drain regions are generally heavily doped regions of the semiconductor substrate. Usually a capped silicide layer, for example, titanium silicide capped by titanium nitride, is used to couple contacts, e.g., active and/or metal contacts, to the source and drain regions. Including a nitrogen-containing capping layer, however, can undesirably contribute to contact resistance (or contact resistivity).

Tungsten (W) is a well-established low resistivity metal for multiple applications including contact, interconnect, and bit line technology. In order to meet the demands of reduced tungsten (W) layer thickness with decreasing technology nodes, however, an increase in resistivity has been observed. There have been approaches developed in attempt to solve the resistivity issue, such as by using other low resistivity metals, including ruthenium (Ru) or molybdenum (Mo). Those approaches, however, either face integration issues or do not result in any resistivity benefit.

Accordingly, there is a need in the art for low resistivity metal stacks and methods of depositing the same.

### SUMMARY

One or more embodiments of the disclosure are directed to a method of depositing a metal stack. In one or more embodiments, the method comprises depositing a tungsten (W) layer on a semiconductor substrate; depositing a molybdenum (Mo) layer on the tungsten (W) layer; depositing a capping layer on the molybdenum (Mo) layer, the capping layer having a thickness in a range of from 5 Å to 25 Å; and depositing a nitride cap layer on the capping layer to form the metal stack.

Additional embodiments of the disclosure are directed to a method of depositing a metal stack. In one or more embodiments, the method comprises depositing a tungsten (W) layer on a semiconductor substrate; depositing a molybdenum (Mo) layer on the tungsten (W) layer; and depositing a nitride cap layer on the molybdenum (Mo) layer in an atmosphere free of ammonia to form the metal stack.

Further embodiments of the disclosure are directed to a metal stack, such as, for example, a metal contact stack. In one or more embodiments, the metal stack comprises: a tungsten (W) layer on a semiconductor substrate; a molybdenum (Mo) layer on the tungsten (W) layer; and a nitride cap layer on the molybdenum (Mo) layer.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2 illustrates a schematic cross-sectional view of a semiconductor substrate in accordance with one or more embodiments of the disclosure;

FIG. 3 illustrates a process flow diagram of a method in accordance with one or more embodiments of the disclosure;

FIG. 4 illustrates a schematic cross-sectional view of a semiconductor substrate in accordance with one or more embodiments of the disclosure;

FIG. 5A illustrates a schematic cross-sectional view of a semiconductor substrate in accordance with one or more embodiments of the disclosure;

FIG. 5B illustrates a schematic cross-sectional view of a semiconductor substrate in accordance with one or more embodiments of the disclosure;

FIG. 5C illustrates a schematic cross-sectional view of a semiconductor substrate in accordance with one or more embodiments of the disclosure;

FIG. 5D illustrates a schematic cross-sectional view of a semiconductor substrate in accordance with one or more embodiments of the disclosure;

FIG. 5E illustrates a schematic cross-sectional view of a semiconductor substrate in accordance with one or more embodiments of the disclosure;

FIG. 6A illustrates a schematic cross-sectional view of a semiconductor substrate in accordance with one or more embodiments of the disclosure;

FIG. 6B illustrates a schematic cross-sectional view of a semiconductor substrate in accordance with one or more embodiments of the disclosure;

FIG. 6C illustrates a schematic cross-sectional view of a semiconductor substrate in accordance with one or more embodiments of the disclosure;

FIG. 6D illustrates a schematic cross-sectional view of a semiconductor substrate in accordance with one or more embodiments of the disclosure; and

FIG. 7 illustrates a schematic view of a cluster tool in accordance with one or more embodiments of the disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

The term “about” as used herein means approximately or nearly and in the context of a numerical value or range set forth means a variation of ±15%, or less, of the numerical value. For example, a value differing by ±14%, ±10%, ±5%, ±2%, or ±1%, would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the figures. For example, if the device in the Figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate surface may have one or more features formed therein, one or more layers formed thereon, and combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls and a bottom extending into the substrate, vias which have one or more sidewall extending into the substrate to a bottom, and slot vias. The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, or 40:1.

The term “on” indicates that there is direct contact between elements. The term “directly on” indicates that there is direct contact between elements with no intervening elements.

As used in this specification and the appended claims, the terms “precursor,” “reactant,” “reactive gas” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., hydrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage-controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source(S) is designated I_{S} and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET) and is used in integrated circuits and high-speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or NMOS FET, then the source and drain are n+ regions and the body is a p-type substrate region. If the MOSFET is a p-channel or PMOS FET, then the source and drain are p+ regions and the body is an n-type substrate region. The source is so named because it is the source of the charge carriers (electrons for n-channel, holes for p-channel) that flow through the channel; similarly, the drain is where the charge carriers leave the channel.

A NMOS FET is made up of an n-type source and drain and a p-type substrate. When a voltage is applied to the gate, holes in the body (p-type substrate) are driven away from the gate. This allows forming an n-type channel between the source and the drain and a current is carried by electrons from source to the drain through an induced n-type channel. Logic gates and other digital devices implemented using NMOSs are said to have NMOS logic. There are three modes of operation in a NMOS called the cut-off, triode, and saturation. Circuits with NMOS logic gates dissipate static power when the circuit is idling, since DC current flows through the logic gate when the output is low.

A PMOS FET is made up of p-type source and drain and an n-type substrate. When a positive voltage is applied between the source and the gate (negative voltage between gate and source), a p-type channel is formed between the source and the drain with opposite polarities. A current is carried by holes from source to the drain through an induced p-type channel. A high voltage on the gate will cause a PMOS not to conduct, while a low voltage on the gate will cause it to conduct. Logic gates and other digital devices implemented using PMOS are said to have PMOS logic. PMOS technology is low cost and has a good noise immunity.

In a NMOS, carriers are electrons, while in a PMOS, carriers are holes. When a high voltage is applied to the gate, NMOS will conduct, while PMOS will not. Furthermore, when a low voltage is applied in the gate, NMOS will not conduct and PMOS will conduct. NMOS are considered to be faster than PMOS, since the carriers in NMOS, which are electrons, travel twice as fast as holes, which are the carriers in PMOS. But PMOS devices are more immune to noise than NMOS devices. Furthermore, NMOS integrated circuits would be smaller than PMOS integrated circuits (that give the same functionality), since the NMOS can provide one-half of the impedance provided by a PMOS (which has the same geometry and operating conditions).

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

These films have been proposed and tested for applications from front-end of line (FEOL) to back-end of line (BEOL) processes and parts of semiconductor and microelectronic devices. Generally, FEOL refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In one or more embodiments, processes are performed without breaking vacuum or without exposure to ambient air.

Embodiments provide low resistivity metal stacks, such as metal contact stacks, and methods of manufacturing low resistivity metal contact stacks having a tungsten (W) layer on a semiconductor substrate and a molybdenum (Mo) layer on the tungsten (W) layer. In specific embodiments pertaining to metal contact stacks, low resistivity metal contact stacks can be used in MOL processes and as MOL parts, including, but not limited to, contact, interconnect, and bit line applications. In one or more embodiments, the low resistivity metal stacks can be used in DRAM cells.

Tungsten (W) is an established low resistivity metal baseline for multiple applications including contact, interconnect, and bit line technology. In order to meet the demands of reduced tungsten (W) layer thickness with decreasing technology nodes, however, an increase in resistivity has been observed. In one or more embodiments, a tungsten/molybdenum (W/Mo) stack is used as a potential substitution for tungsten. using other low resistivity metals, including ruthenium (Ru) or molybdenum (Mo). When a nitride cap layer, e.g., silicon nitride (SiN), is deposited on top of the W/Mo stack, however, molybdenum (Mo) observes a resistivity penalty, which is mainly due to nitridation of the molybdenum to molybdenum nitride (MoN). Accordingly, one or more embodiments advantageously provide methods for reducing the increase in resistivity when using a W/Mo stack.

In one or more embodiments, a thin capping layer of tungsten (W) is advantageously deposited on the molybdenum (Mo) layer. Subsequent deposition of the nitride capping layer does not result in as significant a resistivity penalty as observed when molybdenum (Mo) is used without the tungsten capping layer.

In other embodiments, an ammonia free process is used to deposit the nitride capping layer on the W/Mo stack. This ammonia free deposition of the nitride capping layer does not result in a resistivity penalty. In one or more embodiments, without intending to be bound by theory, it is thought that the ammonia free process prevents, or minimizes, nitridation of the underlying molybdenum (Mo) layer, thus, lower resistivity of the metal stack.

The metal stacks described herein have resistivity benefit over an individual tungsten (W) layer on multiple different substrate materials, including but not limited to, one or more of silicon oxide (SiOx), silicon nitride (SiN), tungsten silicide (WSi), or tungsten silicon nitride (WSiN). It has been advantageously found that the metal stacks described herein are also less substrate dependent compared to an individual tungsten (W) layer.

Some embodiments provide methods including depositing the tungsten (W) layer on the semiconductor substrate, the molybdenum (Mo) layer on the tungsten (W) layer, the tungsten (W) capping layer on the molybdenum (Mo) layer, and the nitride capping layer on the tungsten (W) capping layer (e.g., depositing the metal stack) in situ in an integrated processing tool. Some embodiments provide methods including depositing the tungsten (W) layer on the semiconductor substrate, the molybdenum (Mo) layer on the tungsten (W) layer, the tungsten capping layer on the molybdenum (Mo) layer, and the nitride capping layer on the tungsten capping layer (e.g., depositing the metal stack) including ex situ steps during or after forming the metal stack.

Some embodiments provide methods including depositing the tungsten (W) layer on the semiconductor substrate, the molybdenum (Mo) layer on the tungsten (W) layer, and the nitride capping layer on the molybdenum (Mo) layer (e.g., depositing the metal stack) in an ammonia free process in situ in an integrated processing tool. Some embodiments provide methods including ex situ steps during or after depositing the metal stack.

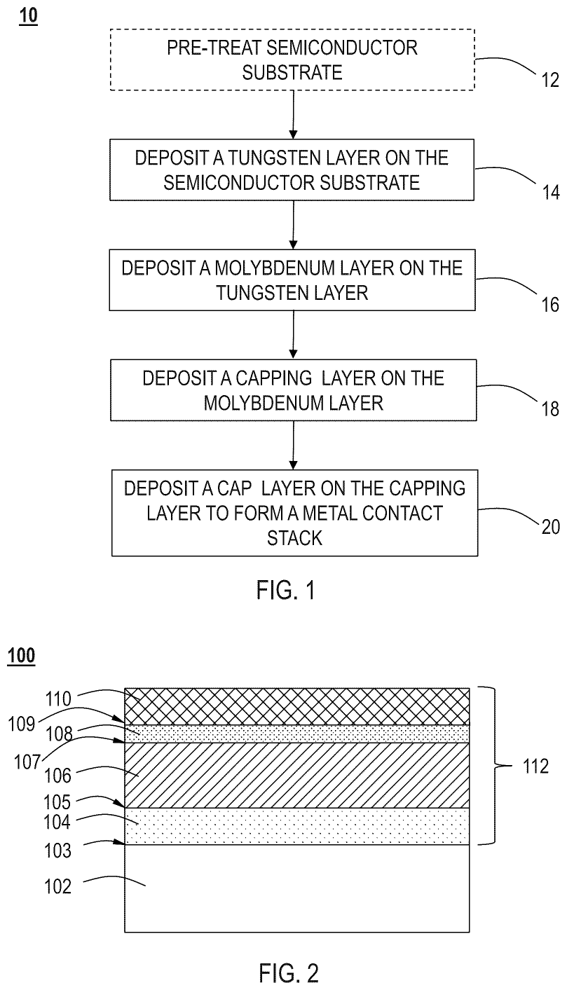

FIG. 1 illustrates a process flow diagram of an exemplary method 10 of depositing a metal stack, such as, for example, a metal contact stack. In particular, FIG. 1 illustrates a method 10 of depositing a metal stack 112 on a semiconductor substrate 102 (shown in FIG. 2).

Referring to FIG. 1 and FIG. 2, in one or more embodiments, the method 10 includes an optional pre-treatment operation 12. The pre-treatment can be any suitable pre-treatment known to the skilled artisan. Suitable pre-treatments include, but are not limited to, pre-heating, cleaning, soaking, or native oxide removal. In one or more embodiments, the pre-treatment comprises polishing, etching, reduction, oxidation, halogenation, hydroxylation, annealing, baking, or the like.

In one or more embodiments, the method 10 includes depositing a tungsten (W) layer 104 on a top surface 103 of the semiconductor substrate 102 (operation 14) and depositing a molybdenum (Mo) layer 106 on a top surface 105 of the tungsten (W) layer 104 (operation 16) to form a metal stack 112.

In one or more embodiments, the metal stack 112 is a metal contact stack that can be used in MOL processes and as MOL parts, including, but not limited to, contact, interconnect, and bit line applications. In one or more embodiments, the metal contact stack (e.g., metal stack 112) can be used in DRAM cells. In one or more embodiments, the metal stack of the Examples (e.g., the Inventive Example) is a metal contact stack that can be used in MOL processes and as MOL parts, including, but not limited to, contact, interconnect, DRAM cell, and bit line applications.

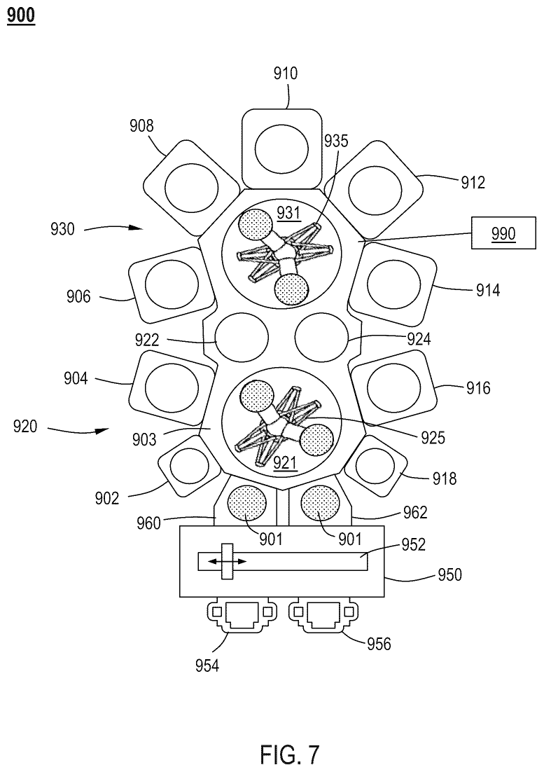

In one or more embodiments, the tungsten (W) layer 104 is deposited directly on the semiconductor substrate 102 and the molybdenum (Mo) layer 106 is deposited directly on the tungsten (W) layer 104. In one or more embodiments, the tungsten (W) layer 104 is deposited directly on the semiconductor substrate 102 and the molybdenum (Mo) layer 106 is deposited directly on the tungsten (W) layer 104 in situ in an integrated processing tool, such as cluster tool 900, described in further detail below with reference to FIG. 7.

In one or more embodiments, the semiconductor substrate 102 comprises one or more of silicon oxide (SiOx), silicon nitride (SiN), tungsten silicide (WSi), or tungsten silicon nitride (WSiN). In one or more embodiments, the semiconductor substrate 102 comprises silicon oxide (SiOx).

In one or more embodiments, one or more of the tungsten (W) layer 104 or the molybdenum (Mo) layer 106 is deposited by sputtering or physical vapor deposition (PVD). In one or more embodiments, one or more of the tungsten (W) layer 104 or the molybdenum (Mo) layer 106 is deposited using a direct current (DC) PVD process or a radiofrequency (RF) PVD process. Accordingly, a tungsten target is sputtered onto the semiconductor substrate 102 to form the tungsten (W) layer 104, and a molybdenum target is sputtered onto the tungsten (W) layer 104 to form the molybdenum (Mo) layer 106 on the tungsten (W) layer 104.

In one or more embodiments, the PVD process comprises RF sputtering and DC and sputtering. In one or more embodiments, the DC is supplied to the semiconductor substrate 102 and the RF is supplied to the metal target (not shown). In one or more embodiments, the DC component has a power in a range of from 0 kilowatt (KW) to 100 KW, 10 KW to 80 KW, 20 KW to 60 KW, 30 KW to 50 KW, or 40 KW to 50 kW. In one or more embodiments, RF component has a power in range of from 0 KW to 10, 1 KW to 10 KW, 3 KW to 10 KW, 5 KW to 10 KW, 7 KW to 10 KW, 1 KW to 7 KW, 3 KW to 7 KW, 5 KW to 7 KW, 1 KW to 5 KW, 3 KW to 5 KW, or 1 KW to 3 kW.

In one or more embodiments, the PVD process occurs at a temperature in a range of from 200° C. to 450° C., 250° C. to 450° C., 300° C. to 450° C., 350° C. to 450° C., 400° C. to 450° C., 200° C. to 400° C., 250° C. to 400° C., 300° C. to 400° C., 350° C. to 400° C., 200° C. to 350° C., 250° C. to 350° C., 300° C. to 350° C., 200° C. to 300° C., 250° C. to 300° C., or 200° C. to 250° C.

In one or more embodiments, the PVD process occurs at a pressure in a range of from 0.5 mTorr to 500 mTorr, 10 mTorr to 500 mTorr, 25 mTorr to 250 mTorr, or 50 m Torr to 150 m Torr.

In one or more embodiments, the tungsten precursor comprises any suitable precursor known to the skilled artisan. The tungsten precursors of one or more embodiments are volatile and thermally stable, and, thus, suitable for vapor deposition. In one or more embodiments, the tungsten precursor comprises a tungsten halide.

As used herein, the term “halide” refers to a binary phase, of which one part is a halogen atom and the other part is an element or radical that is less electronegative than the halogen, to make a fluoride, chloride, bromide, iodide, or astatide compound. A halide ion is a halogen atom bearing a negative charge. As known to those of skill in the art, a halide anion includes fluoride (F—), chloride (Cl—), bromide (Br—), iodide (I—), and astatide (At—). Accordingly, as used herein, the term “tungsten halide” refers to any coordination complex of tungsten with one or more halogen or halide ligand. The term tungsten halide includes tungsten mixed halides which have at least two different halide atoms.

In one or more embodiments, the tungsten (W) layer 104 has a thickness in a range of from 5 Å to 30 Å, or in a range of from 15 Å to 25 Å. In one or more embodiments, the tungsten (W) layer 104 is a continuous layer. Once the predetermined thickness of the tungsten (W) layer 104 has been deposited at operation 14, the method 10 moves to operation 16.

In one or more embodiments, at operation 16, the molybdenum (Mo) layer 106 is deposited directly on the top surface 105 of the tungsten (W) layer 104. In one or more embodiments, the molybdenum precursor used to form the molybdenum (Mo) layer 106 comprises any suitable precursor known to the skilled artisan. The molybdenum precursors of one or more embodiments are volatile and thermally stable, and, thus, suitable for vapor deposition. In one or more embodiments, the molybdenum precursor comprises a molybdenum halide.

The term “molybdenum halide” refers to any coordination complex of molybdenum with one or more halogen or halide ligand. The term molybdenum halide includes molybdenum mixed halides which have at least two different halide atoms.

In one or more embodiments, the molybdenum halide is selected from one or more of molybdenum chloride, molybdenum pentachloride, molybdenum bromide, molybdenum iodide, molybdenum bromochloride, molybdenum bromoiodide, molybdenum chlorobromide, molybdenum chloroiodide, molybdenum iodobromide, molybdenum iodochloride.

In one or more embodiments, the molybdenum precursor comprises a molybdenum oxyhalide species. In one or more embodiments, the molybdenum oxyhalide species comprises one or more of molybdenum tetrachloride oxide (MoCl₄O), molybdenum tetrabromide oxide (MoBr₄O), molybdenum tetraiodide oxide (Mol₄O), molybdenum dibromide dioxide (MoO₂Br₂), molybdenum dichloride dioxide (MoCl₂O₂), and/or molybdenum diiodide dioxide (Mol₂O₂).

In one or more embodiments, the molybdenum (Mo) layer 106 has a thickness in a range of from 80 Å to 200 Å, or in a range of from 100 Å to 150 Å. In one or more embodiments, the molybdenum (Mo) layer 106 is a continuous layer.

Still referring to FIG. 1 and FIG. 2, at operation 18, a thin capping layer 108 is formed on the top surface 107 of the molybdenum (Mo) layer 106. In one or more embodiments, the thin capping layer 108 comprises tungsten (W). The capping layer 108 may have any suitable thickness known to the skilled artisan. In one or more embodiments, the capping layer 108 has a thickness in a range of from 5 Å to 25 Å, including in a range of from 5 Å to 20 Å, or from 10 Å to 20 Å.

At operation 20, a cap layer 110 is formed on a top surface 109 of the capping layer 108. In one or more embodiments, the cap layer 110 comprises any suitable nitride material known to the skilled artisan. In one or more specific embodiments, the cap layer 110 comprises silicon nitride (SiN). The cap layer 110 may have any suitable thickness known to the skilled artisan. In one or more embodiments, the cap layer 110 has a thickness in a range of from 5 Å to 800 Å, including in a range of from 20 Å to 700 Å, or from 5 Å to 600 Å, or from 5 Å to 500 Å, or from 5 Å to 400 Å, or from 5 Å to 300 Å, or from 5 Å to 200 Å, or from 5 Å to 100 Å, or from 5 Å to 75 Å, or from 10 Å to 50 Å.

FIG. 2 illustrates a schematic cross-sectional view of operations 14 through 20 of the method 10 implemented on a device 100 having a semiconductor substrate 102 (or substrate 102).

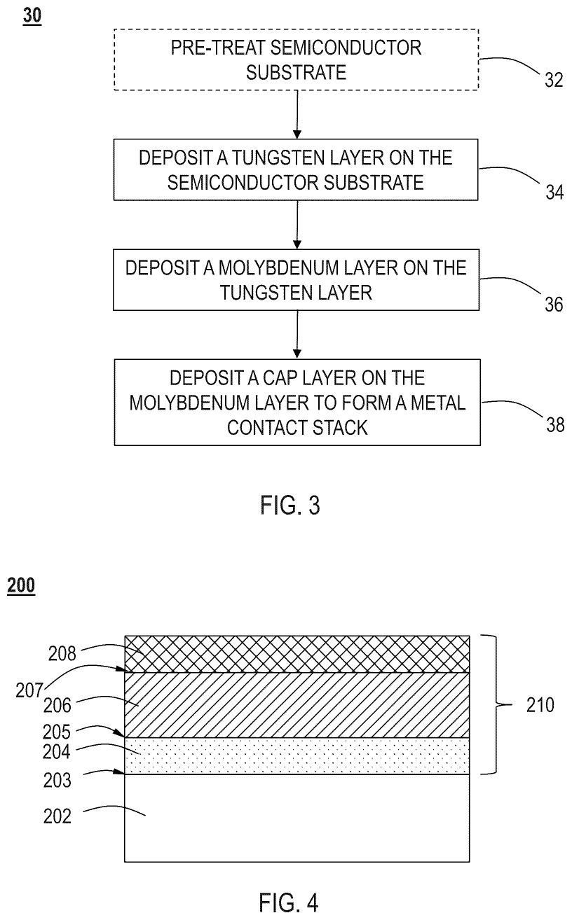

FIG. 3 illustrates a process flow diagram of an exemplary method 30 of depositing a metal stack, such as, for example, a metal contact stack. In particular, FIG. 3 illustrates a method 30 of depositing a metal stack 210 on a semiconductor substrate 202 (shown in FIG. 4).

Referring to FIG. 3 and FIG. 4, in one or more embodiments, the method 30 includes an optional pre-treatment operation 32. The pre-treatment can be any suitable pre-treatment known to the skilled artisan. Suitable pre-treatments include, but are not limited to, pre-heating, cleaning, soaking, or native oxide removal. In one or more embodiments, the pre-treatment comprises polishing, etching, reduction, oxidation, halogenation, hydroxylation, annealing, baking, or the like.

In one or more embodiments, the method 30 includes depositing a tungsten (W) layer 204 on a top surface 203 of the semiconductor substrate 202 (operation 34) and depositing a molybdenum (Mo) layer 206 on a top surface 205 of the tungsten (W) layer 204 (operation 36) to form a metal stack 210.

In one or more embodiments, the metal stack 210 is a metal contact stack that can be used in MOL processes and as MOL parts, including, but not limited to, contact, interconnect, and bit line applications. In one or more embodiments, the metal contact stack (e.g., metal stack 210) can be used in DRAM cells. In one or more embodiments, the metal stack of the Examples (e.g., the Inventive Example) is a metal contact stack that can be used in MOL processes and as MOL parts, including, but not limited to, contact, interconnect, DRAM cell, and bit line applications.

In one or more embodiments, the tungsten (W) layer 204 is deposited directly on the semiconductor substrate 202 and the molybdenum (Mo) layer 206 is deposited directly on the tungsten (W) layer 204. In one or more embodiments, the tungsten (W) layer 204 is deposited directly on the semiconductor substrate 202 and the molybdenum (Mo) layer 206 is deposited directly on the tungsten (W) layer 204 in situ in an integrated processing tool, such as cluster tool 900, described in further detail below with reference to FIG. 7.

In one or more embodiments, the semiconductor substrate 202 comprises one or more of silicon oxide (SiOx), silicon nitride (SiN), tungsten silicide (WSi), or tungsten silicon nitride (WSiN). In one or more embodiments, the semiconductor substrate 202 comprises silicon oxide (SiOx).

In one or more embodiments, one or more of the tungsten (W) layer 204 or the molybdenum (Mo) layer 206 is deposited by sputtering or physical vapor deposition (PVD). In one or more embodiments, one or more of the tungsten (W) layer 204 or the molybdenum (Mo) layer 206 is deposited using a direct current (DC) PVD process or a radiofrequency (RF) PVD process. Accordingly, a tungsten target is sputtered onto the semiconductor substrate 202 to form the tungsten (W) layer 204, and a molybdenum target is sputtered onto the tungsten (W) layer 204 to form the molybdenum (Mo) layer 106 on the tungsten (W) layer 204.

In one or more embodiments, the PVD process comprises RF sputtering and DC and sputtering. In one or more embodiments, the DC is supplied to the semiconductor substrate 202 and the RF is supplied to the metal target (not shown). In one or more embodiments, the DC component has a power in a range of from 0 kilowatt (KW) to 100 KW, 10 KW to 80 KW, 20 KW to 60 KW, 30 KW to 50 KW, or 40 kW to 50 kW. In one or more embodiments, RF component has a power in range of from 0 KW to 10, 1 KW to 10 KW, 3 KW to 10 KW, 5 KW to 10 KW, 7 KW to 10 KW, 1 KW to 7 KW, 3 KW to 7 kW, 5 KW to 7 KW, 1 KW to 5 KW, 3 KW to 5 KW, or 1 KW to 3 KW.

In one or more embodiments, the PVD process occurs at a temperature in a range of from 200° C. to 450° C., 250° C. to 450° C., 300° C. to 450° C., 350° C. to 450° C., 400° C. to 450° C., 200° C. to 400° C., 250° C. to 400° C., 300° C. to 400° C., 350° C. to 400° C., 200° C. to 350° C., 250° C. to 350° C., 300° C. to 350° C., 200° C. to 300° C., 250° C. to 300° C., or 200° C. to 250° C.

In one or more embodiments, the PVD process occurs at a pressure in a range of from 0.5 mTorr to 500 mTorr, 10 mTorr to 500 mTorr, 25 mTorr to 250 m Torr, or 50 mTorr to 150 m Torr.

In one or more embodiments, the tungsten precursor comprises any suitable precursor known to the skilled artisan. The tungsten precursors of one or more embodiments are volatile and thermally stable, and, thus, suitable for vapor deposition. In one or more embodiments, the tungsten precursor comprises a tungsten halide.

In one or more embodiments, the tungsten (W) layer 204 has a thickness in a range of from 5 Å to 30 Å, or in a range of from 15 Å to 25 Å. In one or more embodiments, the tungsten (W) layer 204 is a continuous layer. Once the predetermined thickness of the tungsten (W) layer 204 has been deposited at operation 34, the method 30 moves to operation 36.

In one or more embodiments, at operation 36, the molybdenum (Mo) layer 106 is deposited directly on the top surface 205 of the tungsten (W) layer 204. In one or more embodiments, the molybdenum precursor used to form the molybdenum (Mo) layer 206 comprises any suitable precursor known to the skilled artisan. The molybdenum precursors of one or more embodiments are volatile and thermally stable, and, thus, suitable for vapor deposition. In one or more embodiments, the molybdenum precursor comprises a molybdenum halide.

In one or more embodiments, the molybdenum halide is selected from one or more of molybdenum chloride, molybdenum pentachloride, molybdenum bromide, molybdenum iodide, molybdenum bromochloride, molybdenum bromoiodide, molybdenum chlorobromide, molybdenum chloroiodide, molybdenum iodobromide, molybdenum iodochloride.

In one or more embodiments, the molybdenum precursor comprises a molybdenum oxyhalide species. In one or more embodiments, the molybdenum oxyhalide species comprises one or more of molybdenum tetrachloride oxide (MoCl₄O), molybdenum tetrabromide oxide (MoBr₄O), molybdenum tetraiodide oxide (Mol₄O), molybdenum dibromide dioxide (MoO₂Br₂), molybdenum dichloride dioxide (MoCl₂O₂), and/or molybdenum diiodide dioxide (Mol₂O₂).

In one or more embodiments, the molybdenum (Mo) layer 206 has a thickness in a range of from 80 Å to 200 Å, or in a range of from 100 Å to 150 Å. In one or more embodiments, the molybdenum (Mo) layer 206 is a continuous layer. Still referring to FIG. 3 and FIG. 4, at operation 38, a cap layer 208 is formed on a top surface 207 of the molybdenum (Mo) layer 206. In one or more embodiments, the cap layer 208 comprises any suitable nitride material known to the skilled artisan. In one or more specific embodiments, the cap layer 108 comprises silicon nitride (SiN). The cap layer 208 may have any suitable thickness known to the skilled artisan. In one or more embodiments, the cap layer 208 has a thickness in a range of from thickness in a range of from 5 Å to 800 Å, including in a range of from 20 Å to 700 Å, or from 5 Å to 600 Å, or from 5 Å to 500 Å, or from 5 Å to 400 Å, or from 5 Å to 300 Å, or from 5 Å to 200 Å, or from 5 Å to 100 Å, or from 5 Å to 75 Å, or from 10 Å to 50 Å.

In one or more embodiments, the cap layer 208 is formed by an ammonia free process. In one or more embodiments, the cap layer 208 comprises silicon nitride. In one or more embodiments, the cap layer 208 is deposited using an atomic layer deposition (ALD) technique without the use of ammonia. In one or more embodiments, the cap layer 208 is deposited using an ammonia free deposition technique, such as but not limited to a CVD, PVD, MBE, MOCVD, spin-on, or other deposition techniques without the presence of ammonia known to one of ordinary skill in the art of semiconductor device manufacturing. Without intending to be bound by theory, it is thought that the cap layer 208 formed without ammonia prevents nitridation of the underlying molybdenum (Mo) layer 206, thus preventing an increase in resistivity.

In one or more embodiments, the cap layer 208 is formed by an ammonia free process, including, but not limited to nitrogen plasma. As used herein, the phrase “ammonia free process” or “process free of ammonia” means that there is less than 5%, less than 4%, less than 3%, less than 2%, or less than 1% of ammonia present in the atmosphere in which the cap layer 208 is formed. Without intending to be bound by theory, it is thought that forming the cap layer 208 in an atmosphere free of ammonia, e.g., in an ammonia free process, will result in the underlying molybdenum (Mo) layer 206 not forming molybdenum nitride (MoN) and thus will lead to a lower resistivity metal stack 210.

FIG. 4 illustrates a schematic cross-sectional view of operations 34 through 38 of the method 30 implemented on a device 200 having a semiconductor substrate 202 (or substrate 202).

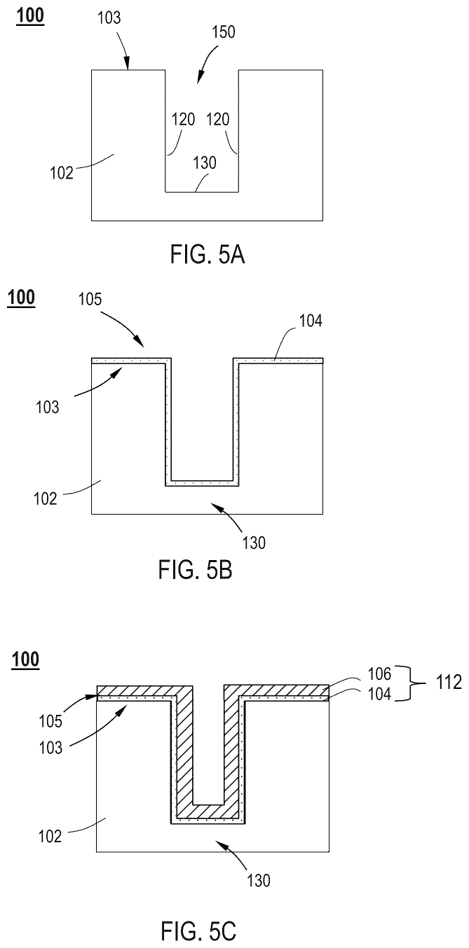

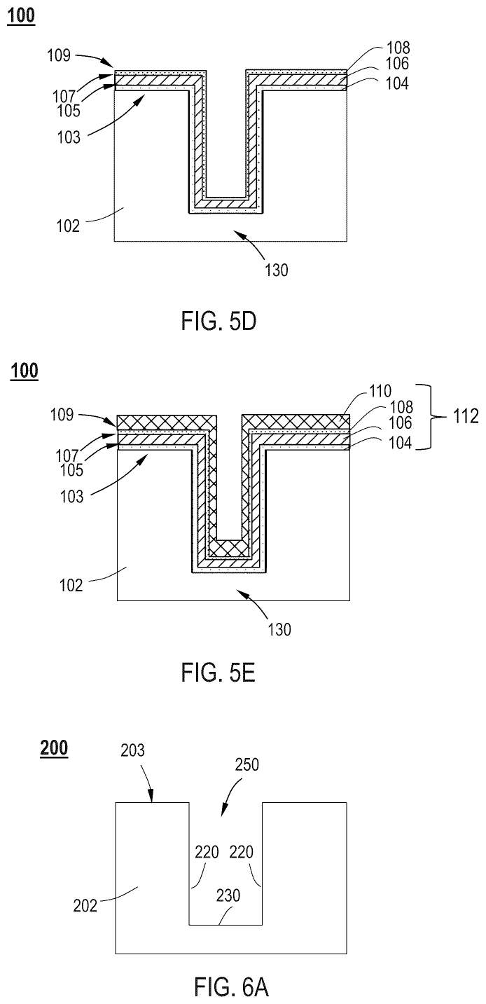

FIGS. 5A-5E illustrate schematic cross-sectional views of the method 10 (FIG. 1) implemented on a device 100 having a semiconductor substrate 102 (or substrate 102) that includes at least one feature 150 that has a gap defined by a top surface 103, two opposing sidewalls 120, and a bottom surface 130. The two opposing sidewalls 120 may comprise any suitable material. In one or more embodiments, the two opposing sidewalls 120 comprise a dielectric material, e.g., a low-K dielectric material such as, but not limited to, silicon oxide (SiOx), silicon sub-oxides, silicon nitride (SiₓN_{y}), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof. The bottom surface 130 may comprise any suitable material, such as a metallic material.

In FIG. 5A, the substrate 102 is shown having a single feature 150 therein. In FIG. 5B, in one or more embodiments, a deposited tungsten (W) layer 104 is shown directly on the top surface 103 and along the two opposing sidewalls 120 and the bottom surface 130. In FIG. 5C, a deposited molybdenum (Mo) layer 106 is shown directly on the top surface 105 of the deposited tungsten (W) layer 104.

The Figures show the substrate 102 having a single feature 150 for illustrative purposes; however, those skilled in the art will understand that there can be more than one feature 150. The shape of the feature 150 can be any suitable shape including, but not limited to, trenches and cylindrical vias, as described herein.

In one or more embodiments, the at least one feature 150 comprises one or more of a trench or a via. In specific embodiments, the at least one feature 150 comprises a trench. In still further embodiments, the term “at least one feature 150” and “trench 150” may be used interchangeably. The trench 150 has a depth to the bottom surface 130 and a width between the two opposing sidewalls 120. In one or more embodiments, the depth is in a range of 2 nm to 200 nm, 3 nm to 200 nm, 5 nm to 100 nm, 2 nm to 100 nm, or 50 nm to 100 nm. In one or more embodiments, the width is in a range of 10 nm to 100 nm, 10 nm to 20 nm, 10 nm to 50 nm, or 50 nm to 100 nm. In one or more embodiments, the aspect ratio of the trench 550 described herein is greater than or equal to about 1:1, 2:1, 5:1, 10:1, 15:1, 20:1, 25:1, 30:1, 35:1, or 40:1.

The molybdenum (Mo) layer 106 of some embodiments fills the gap formed by the feature 150 in a bottom-up manner. As used in this manner, “bottom-up” means that the deposition occurs substantially on the bottom surface 130 of the feature 150 relative to the sidewalls 120.

Referring to FIG. 5D, a capping layer 108 is deposited on the top surface 107 of the molybdenum (Mo) layer 107. The capping layer 108 may comprise tungsten (W), as described above. With reference to FIG. 5E, a cap layer 110 is formed on the top surface 109 of the capping layer 108. The cap layer 110 may comprise silicon nitride (SiN), as described above. After the nitride cap layer 110 is deposited on the capping layer 508, metal stack 112 is formed.

In one or more embodiments, a resistivity (μΩ-cm) is measured for the metal stack 112 having a total thickness of 200 Å. In one or more embodiments, the total thickness of 200 Å includes the tungsten (W) layer 104 having a thickness in a range of from 5 Å to 30 Å, the molybdenum (Mo) layer 106 having a thickness in a range of from 110 Å to 135 Å, the capping layer 108 having a thickness in a range of from 5 Å to 25 Å, and the cap layer 110 having a thickness in a range of from 5 Å to 70 Å. In one or more embodiments, the total thickness of 200 Å includes the tungsten (W) layer 104 having a thickness in a range of from 15 Å to 25 Å, the molybdenum (Mo) layer 106 having a thickness in a range of from 115 Å to 125 Å, the capping layer 108 having a thickness in a range of from 10 Å to 20 Å, and a cap layer 110 having a thickness in a range of from 15 Å to 75 Å. In one or more embodiments, the metal stack 112 deposited by the method 10, according to one or more embodiments, advantageously has a resistivity of less than or equal to 10 μΩ-cm when the total thickness of the metal stack 112 is 200 Å.

In one or more embodiments, the metal stack 112 deposited by the method 10, according to one or more embodiments, advantageously has a resistivity of less than or equal to 10 μΩ-cm or less than or equal to 9 μΩ-cm when the total thickness of the metal stack is 200 Å. Advantageously, the annealed metal stack 112 has a resistivity of less than or equal to 11 μΩ-cm when the total thickness of the metal stack 112 is 200 Å. Even after annealing, the metal stack 112 described herein advantageously has a lower resistivity than tungsten (W), or molybdenum (Mo), individually.

According to one or more embodiments, the substrate 102 may be subjected to processing prior to (optional operation 12) and/or after depositing the metal stack 112. In one or more embodiments, the method 10 includes depositing a tungsten (W) layer 104 on a top surface 103 of a semiconductor substrate 102 (operation 14), depositing a molybdenum (Mo) layer 106 on a top surface 105 of the tungsten (W) layer 104 (operation 16), depositing a tungsten capping layer 108 on a top surface 107 of the molybdenum (Mo) layer 106 (operation 18), and depositing a cap layer 110 on a top surface (109) of the capping layer 108 (operation 20) to form the metal stack 112. In one or more embodiments, depositing the tungsten (W) layer 104 on the semiconductor substrate 102, the molybdenum (Mo) layer 106 on the tungsten (W) layer 104, the tungsten (W) capping layer 108 on the molybdenum (Mo) layer 106, and the nitride capping layer 110 on the tungsten (W) capping layer 108 (e.g., depositing the metal stack 112) is performed in situ in an integrated processing tool where the semiconductor substrate 102 is maintained at a temperature in a range of from 200° C. to 400° C. Some embodiments provide methods include ex situ steps during or after depositing the metal stack.

The substrate 102 can be processed in single substrate deposition chambers, where a single substrate is loaded, processed, and unloaded before another substrate is processed. The substrate 102 can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

The substrate 102 can also be stationary or rotated during processing. A rotating substrate can be rotated (about the substrate axis) continuously or in discrete steps. For example, a substrate 102 may be rotated continuously throughout the entire process or in steps. Rotating the substrate during processing (either continuously or in steps) may help produce a more uniform deposition by minimizing the effect of, for example, local variability in sputtering geometries.

The substrate 102 may be processed according to method 10 (e.g., performing operations in situ and ex situ) in a processing apparatus having multiple chambers in communication with a transfer station. An apparatus of this sort may be referred to as a “cluster tool” or “clustered system,” and the like.

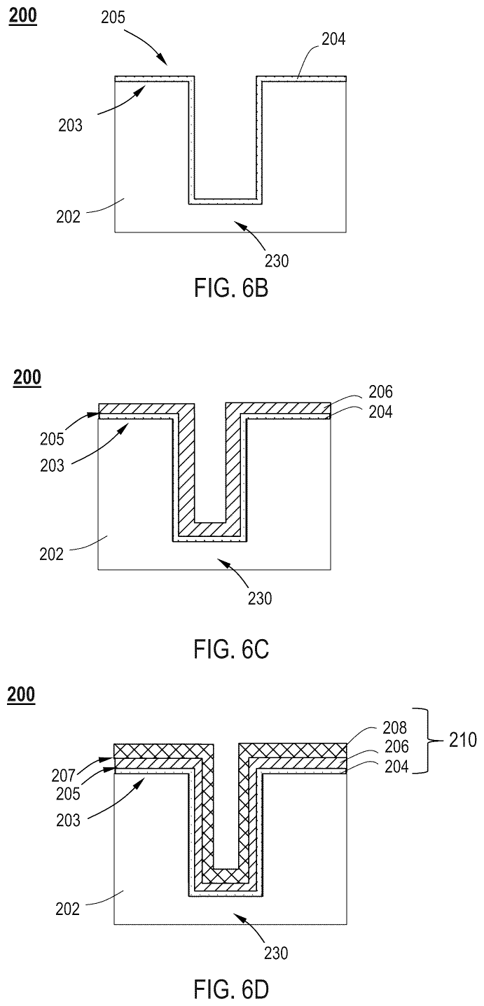

FIGS. 6A-6D illustrate schematic cross-sectional views of the method 30 (FIG. 3) implemented on a device 200 having a semiconductor substrate 202 (or substrate 202) that includes at least one feature 250 that has a gap defined by a top surface 203, two opposing sidewalls 220, and a bottom surface 230. The two opposing sidewalls 220 may comprise any suitable material. In one or more embodiments, the two opposing sidewalls 220 comprise a dielectric material, e.g., a low-K dielectric material such as, but not limited to, silicon oxide (SiOx), silicon sub-oxides, silicon nitride (SiₓN_{y}), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof. The bottom surface 230 may comprise any suitable material, such as a metallic material.

In FIG. 6A, the substrate 202 is shown having a single feature 250 therein. In FIG. 6B, in one or more embodiments, a deposited tungsten (W) layer 204 is shown directly on the top surface 203 and along the two opposing sidewalls 220 and the bottom surface 230. In FIG. 6C, a deposited molybdenum (Mo) layer 206 is shown directly on the top surface 205 of the deposited tungsten (W) layer 204.

The Figures show the substrate 202 having a single feature 250 for illustrative purposes; however, those skilled in the art will understand that there can be more than one feature 250. The shape of the feature 250 can be any suitable shape including, but not limited to, trenches and cylindrical vias, as described herein.

In one or more embodiments, the at least one feature 250 comprises one or more of a trench or a via. In specific embodiments, the at least one feature 250 comprises a trench. In still further embodiments, the term “at least one feature 250” and “trench 250” may be used interchangeably. The trench 250 has a depth to the bottom surface 230 and a width between the two opposing sidewalls 220. In one or more embodiments, the depth is in a range of 2 nm to 200 nm, 3 nm to 200 nm, 5 nm to 100 nm, 2 nm to 100 nm, or 50 nm to 100 nm. In one or more embodiments, the width is in a range of 10 nm to 100 nm, 10 nm to 20 nm, 10 nm to 50 nm, or 50 nm to 100 nm. In one or more embodiments, the aspect ratio of the trench 250 described herein is greater than or equal to about 1:1, 2:1, 5:1, 10:1, 15:1, 20:1, 25:1, 30:1, 35:1, or 40:1.

The molybdenum (Mo) layer 206 of some embodiments fills the gap formed by the feature 250 in a bottom-up manner. As used in this manner, “bottom-up” means that the deposition occurs substantially on the bottom surface 230 of the feature 250 relative to the sidewalls 220.

Referring to FIG. 6D, a cap layer 208 is deposited on the top surface 207 of the molybdenum (Mo) layer 207. The cap layer 208 may comprise silicon nitride (SiN), as described above. After the nitride cap layer 208 is deposited on the molybdenum (Mo) layer 208, metal stack 210 is formed. In one or more embodiments, the cap layer 208 is formed by an ammonia free process.

In one or more embodiments, a resistivity (μΩ-cm) is measured for the metal stack 210 having a total thickness of 200 Å. In one or more embodiments, the total thickness of 200 Å includes the tungsten (W) layer 204 having a thickness in a range of from 5 Å to 30 Å, the molybdenum (Mo) layer 206 having a thickness in a range of from 110 Å to 135 Å, and the cap layer 208 having a thickness in a range of from 5 Å to 70 Å. In one or more embodiments, the total thickness of 200 Å includes the tungsten (W) layer 204 having a thickness in a range of from 15 Å to 25 Å, the molybdenum (Mo) layer 206 having a thickness in a range of from 115 Å to 125 Å, and the cap layer 208 having a thickness in a range of from 15 Å to 75 Å that was formed in an atmosphere free of ammonia. In one or more embodiments, the metal stack 210 deposited by the method 30, according to one or more embodiments, advantageously has a resistivity of less than or equal to 10 μΩ-cm, or less than or equal to 8 μΩ-cm, or less than or equal to 7.5μΩ-cm when the total thickness of the metal stack 210 is 200 Å.

In one or more embodiments, the metal stack 210 deposited by the method 30, according to one or more embodiments, advantageously has a resistivity of less than or equal to 10 μΩ-cm or less than or equal to 9 μΩ-cm or less than or equal to 8 μΩ-cm when the total thickness of the metal stack 210 is 200 Å. Advantageously, the annealed metal stack 210 has a resistivity of less than or equal to 11 μΩ-cm or less than or equal to 10 μΩ-cm or less than or equal to 9 μΩ-cm when the total thickness of the metal stack 210 is 200 Å. Even after annealing, the metal stack 210 described herein advantageously has a lower resistivity than tungsten (W), or molybdenum (Mo), individually.

According to one or more embodiments, the substrate 202 may be subjected to processing prior to (optional operation 32) and/or after depositing the metal stack 210. In one or more embodiments, the method 30 includes depositing a tungsten (W) layer 204 on a top surface 203 of a semiconductor substrate 202 (operation 34), depositing a molybdenum (Mo) layer 206 on a top surface 205 of the tungsten (W) layer 204 (operation 36), and depositing a cap layer 208 on a top surface (207) of the molybdenum layer 206 (operation 38) to form the metal stack 210. In one or more embodiments, depositing the tungsten (W) layer 204 on the semiconductor substrate 202, the molybdenum (Mo) layer 206 on the tungsten (W) layer 204, and the cap layer 208 on the molybdenum (Mo) layer 206 (e.g., depositing the metal stack 210) without the presence of ammonia is performed in situ in an integrated processing tool where the semiconductor substrate 202 is maintained at a temperature in a range of from 200° C. to 400° C. Some embodiments provide methods include ex situ steps during or after depositing the metal stack.

The substrate 202 can be processed in single substrate deposition chambers, where a single substrate is loaded, processed, and unloaded before another substrate is processed. The substrate 202 can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

The substrate 202 can also be stationary or rotated during processing. A rotating substrate can be rotated (about the substrate axis) continuously or in discrete steps. For example, a substrate 202 may be rotated continuously throughout the entire process or in steps. Rotating the substrate during processing (either continuously or in steps) may help produce a more uniform deposition by minimizing the effect of, for example, local variability in sputtering geometries.

The substrate 202 may be processed according to method 10 (e.g., performing operations in situ and ex situ) in a processing apparatus having multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool.

Processing chambers which may be adapted for the present disclosure include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in a chamber on a cluster tool, surface contamination of the substrate with atmospheric impurities can be avoided without oxidation prior to depositing metal layers (including the metal stack).

Embodiments of the disclosure are directed to cluster tools 900 for the formation of the devices and methods described, as shown in FIG. 7.

The cluster tool 900 includes at least one central transfer station 921, 931 with a plurality of sides. A robot 925, 935 is positioned within the central transfer station 921, 931 and is configured to move a robot blade and a wafer (e.g., the semiconductor substrate 202) to each of the plurality of sides.

The cluster tool 900 comprises a plurality of processing chambers 902, 904, 906, 908, 910, 912, 914, 916, and 918, also referred to as process stations, connected to the central transfer station. The various processing chambers provide separate processing regions isolated from adjacent process stations. The processing chamber can be any suitable chamber including, but not limited to, a preclean chamber, a buffer chamber, transfer space(s), a wafer orienter/degas chamber, a cryo cooling chamber, a deposition chamber (e.g., a sputtering or PVD chamber), annealing chamber, and etching chamber. The particular arrangement of process chambers and components can be varied depending on the cluster tool and should not be taken as limiting the scope of the disclosure.

In one or more embodiments, the plurality of processing chambers 902, 904, 906, 908, 910, 912, 914, 916, and 918 includes one or more PVD chambers for depositing the tungsten (W) layer 104, 204 on the semiconductor substrate 102, 202; and depositing the molybdenum (Mo) layer 106, 206 on the tungsten (W) layer 102, 204 to form the metal stack. In one or more embodiments, each of the tungsten (W) layer 104, 204 and the molybdenum (Mo) layer 106, 206 are deposited in the different PVD chambers in situ, e.g., two of the plurality of processing chambers 902, 904, 906, 908, 910, 912, 914, 916, and 918.

In the illustrated embodiment of FIG. 7, a factory interface 950 is connected to a front of the cluster tool 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates (e.g., semiconductor substrate 202) being processed in the cluster tool 900. In the illustrated embodiment of FIG. 7, the loading chamber 954 and unloading chamber 956 are sized to hold a wafer cassette with a plurality of wafers (e.g., a plurality of semiconductor substrates 202) positioned within the cassette.

A robot 952 is within the factory interface 950 and can move between the loading chamber 954 and the unloading chamber 956. The robot 952 is capable of transferring a wafer from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

The cluster tool 900 shown has a first section 920 and a second section 930. The first section 920 is connected to the factory interface 950 through load lock chambers 960, 962. The first section 920 includes a first transfer chamber 921 with at least one robot 925 positioned therein. The robot 925 is also referred to as a robotic wafer transport mechanism. The first transfer chamber 921 is centrally located with respect to the load lock chambers 960, 962, process chambers 902, 904, 916, 918, and buffer chambers 922, 924. The robot 925 of some embodiments is a multi-arm robot capable of independently moving more than one wafer at a time. In one or more embodiments, the first transfer chamber 921 comprises more than one robotic wafer transfer mechanism. The robot 925 in first transfer chamber 921 is configured to move wafers between the chambers around the first transfer chamber 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930 or allow water cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits, and storage.

Processes may generally be stored in the memory of the system controller 990 as a software routine that, when executed by the processor, causes the process chamber to perform processes of the present disclosure. The software routine may also be stored and/or executed by a second processor (not shown) that is remotely located from the hardware being controlled by the processor. Some or all operations of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Comparative Example 1

A metal stack comprising a tungsten (W) layer having a thickness of 140 Å was deposited on a silicon oxide (SiOx) substrate. The sheet resistance of the deposited metal stack was about to 9.0 Ω/sq on the substrate.

### Comparative Example 2

A metal stack comprising a tungsten (W) layer having a thickness of 140 Å was deposited on a silicon oxide (SiOx) substrate. A silicon nitride (SiN) capping layer was deposited on the tungsten layer. The sheet resistance of the deposited metal stack increased to by 6% from 9.0 Ω/sq (Example 1) to about 9.5 Ω/sq.

### Comparative Example 3

A metal stack comprising tungsten layer having a thickness of about 10 Å was deposited on a silicon oxide (SiOx) substrate. A molybdenum (Mo) layer having a thickness of 120 Å was deposited on the tungsten (W) layer. The sheet resistance of the metal stack was about 7 Ω/sq.

### Comparative Example 4

A metal stack comprising tungsten layer having a thickness of about 20 Å was deposited on a silicon oxide (SiOx) substrate. A molybdenum (Mo) layer having a thickness of 120 Å was deposited on the tungsten (W) layer. A silicon nitride (SiN) capping layer was deposited on the molybdenum (Mo) layer. The resulting sheet resistance of the metal stack increased by about 43% from about 7 Ω/sq (Example 3) to about 9 Ω/sq.

### Comparative Example 5

A metal stack comprising tungsten layer having a thickness of about 20 Å was deposited on a silicon oxide (SiOx) substrate. A molybdenum (Mo) layer having a thickness of 120 Å was deposited on the tungsten (W) layer. A tungsten (W) capping layer having a thickness of 10 Å was deposited on the molybdenum (Mo) layer. The sheet resistance of the metal stack was about 7.5 Ω/sq.

### Inventive Example 6

A metal stack comprising tungsten layer having a thickness of about 20 Å was deposited on a silicon oxide (SiOx) substrate. A molybdenum (Mo) layer having a thickness of 120 Å was deposited on the tungsten (W) layer. A tungsten (W) capping layer having a thickness of 10 Å was deposited on the molybdenum (Mo) layer. A silicon nitride (SiN) capping layer was deposited on the tungsten (W) capping layer. The resulting sheet resistance of the metal stack increased by about 21% from about 7.5 Ω/sq (Example 5) to about 9 Ω/sq.

### Inventive Example 7

A metal stack comprising tungsten layer having a thickness of about 20 Å was deposited on a silicon oxide (SiOx) substrate. A molybdenum (Mo) layer having a thickness of 120 Å was deposited on the tungsten (W) layer. A silicon nitride (SiN) capping layer was deposited on the molybdenum (Mo) layer using an ammonia free process. The resulting sheet resistance of the metal stack increased by about 1% from about 7 Ω/sq (Example 3) to about 7.1 Ω/sq.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of depositing a metal stack, the method comprising:
depositing a tungsten (W) layer on a semiconductor substrate;
depositing a molybdenum (Mo) layer on the tungsten (W) layer;
depositing a capping layer on the molybdenum (Mo) layer, the capping layer having a thickness in a range of from 5 Å to 25 Å; and
depositing a nitride cap layer on the capping layer to form the metal stack.

2. The method of claim 1, wherein the capping layer has a thickness in a range of from 10 Å to 20 Å.

3. The method of claim 1, wherein the capping layer comprises tungsten (W).

4. The method of claim 1, wherein the nitride cap layer comprises silicon nitride (SiN).

5. The method of claim 1, wherein the nitride cap layer has a thickness in a range of from 30 Å to 800 Å.

6. The method of claim 1, wherein the tungsten (W) layer has a thickness in a range of from 5 Å to 30 Å.

7. The method of claim 1, wherein the molybdenum (Mo) layer has a thickness in a range of from 80 Å to 200 Å.

8. The method of claim 1, performed in situ in an integrated processing tool.

9. The method of claim 1, wherein the metal stack has a resistivity of less than or equal to 10 Ω/sq when the metal stack has a total thickness of 200 Å.

10. A method of depositing a metal stack, the method comprising:
depositing a tungsten (W) layer on a semiconductor substrate;
depositing a molybdenum (Mo) layer on the tungsten (W) layer; and
depositing a nitride cap layer on the molybdenum (Mo) layer in an atmosphere free of ammonia to form the metal stack.

11. The method of claim 10, wherein the nitride cap layer comprises silicon nitride (SiN).

12. The method of claim 10, wherein the nitride cap layer has a thickness in a range of from 30 Å to 800 Å.

13. The method of claim 10, wherein the tungsten (W) layer has a thickness in a range of from 5 Å to 30 Å and the molybdenum (Mo) layer has a thickness in a range of from 80 Å to 200 Å.

14. The method of claim 13, wherein the thickness of the tungsten (W) layer is in a range of from 15 Å to 25 Å and the thickness of the molybdenum (Mo) layer is in a range of from 100 Å to 150 Å.

15. The method of claim 10, wherein the metal stack has a resistivity of less than or equal to 8 Ω/sq and the metal stack has a total thickness of 200 Å.

16. A metal stack comprising:
a tungsten (W) layer on a semiconductor substrate;
a molybdenum (Mo) layer on the tungsten (W) layer; and
a nitride cap layer on the molybdenum (Mo) layer.

17. The metal stack of claim 16, further comprising a capping layer between the molybdenum (Mo) layer and the nitride cap layer.

18. The metal stack of claim 16, wherein the nitride cap layer comprises silicon nitride (SiN).

19. The metal stack of claim 16, wherein the nitride cap layer has a thickness in a range of from 30 Å to 800 Å.

20. The metal stack of claim 17, wherein the capping layer has a thickness in a range of from 5 Å to 25 Å.
